(19) United States
(12) Patent Application Publication
(10) Pub. No.: US 2010/0303116 A1
(43) Pub. Date: Dec. 2, 2010

(54) SEMICONDUCTOR LASER DEVICE AND OPTICAL APPARATUS EMPLOYING THE SAME

(75) Inventors: Yoshiki Murayama, Tottori-shi (JP); Shingo Kameyama, Ibaraki-shi (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/790,006

(22) Filed: May 28, 2010

(30) Foreign Application Priority Data
May 29, 2009 (JP) 2009-130947

(51) Int. Cl. H01S 5/028

(52) U.S. Cl. 372/49.01

(57) ABSTRACT

This semiconductor laser device includes a semiconductor element layer having an active layer and a cavity facet and a facet coating film arranged on the cavity facet, while the facet coating film includes an oxide film made of hafnium silicate (HfSiO) or hafnium aluminate (HfAlO), and the facet coating film further has a nitrogen-containing film, in contact with the cavity facet, between the cavity facet and the oxide film.

### CROSS-REFERENCE TO RELATED APPLICATION

The priority application number JP2009-130947, Semiconductor Laser Device and Optical Pickup employing the Same, May 29, 2009, Yoshiki Murayama et al., upon which this patent application is based is hereby incorporated by reference.

### BACKGROUND OF THE INVENTION

1. Field of the Invention

The present invention relates to a semiconductor laser device and an optical apparatus employing the same, and more particularly, it relates to a semiconductor laser device having a facet coating film formed on a cavity facet and an optical apparatus employing the same.

2. Description of the Background Art

In recent years, facet coating films of various materials and structures have been developed as those formed on cavity facets of semiconductor laser devices. For example, Japanese Patent Laying-Open No. 2008-47692 discloses a semiconductor laser device including such a facet coating film.

The aforementioned Japanese Patent Laying-Open No. 2008-47692 discloses a semiconductor laser device having a light-emitting side reflecting film containing at least one of SiO₂, Al₂O₂, HfO₂ etc. formed on a front facet of a semiconductor layer, made of an AlGaInN-based compound semiconductor, including an active layer.

In the conventional semiconductor laser device disclosed in the aforementioned Japanese Patent Laying-Open No. 2008-47692, however, a facet coating film remarkably generates heat due to light absorption or the like, following wavelength shortening and a higher output of a laser beam. If HfO₂ having a small absorption coefficient in a short wave range is employed, the facet coating film is disadvantageously easily crystallized due to the low crystallization temperature of HfO₂ of about several 100° C., and the optical characteristics thereof are disadvantageously easily changed. Particularly when a facet coating film consisting of an oxide film is formed on a cavity facet of a nitride-based semiconductor laser device, the interface between the cavity facet and the facet coating film is disadvantageously deteriorated due to diffusion of oxygen from the external atmosphere into the facet coating film. Consequently, the reliability of the conventional semiconductor laser device is disadvantageously easily reduced due to wavelength shortening and a higher output of a laser beam.

### SUMMARY OF THE INVENTION

A semiconductor laser device according to a first aspect of the present invention includes a semiconductor element layer having an active layer and a cavity facet and a facet coating film arranged on the cavity facet, while the facet coating film includes an oxide film made of hafnium silicate (HfSiO) or hafnium aluminate (HfAlO), and the facet coating film further has a nitrogen-containing film, in contact with the cavity facet, between the cavity facet and the oxide film.

In the semiconductor laser device according to the first aspect of the present invention, as hereinabove described, the facet coating film formed on the cavity facet has the oxide film made of HfSiO or HfAlO. The oxide film of such a material has a crystallization temperature of at least 1000° C. and is superior in thermal stability as compared with HfO₂, whereby optical characteristics are hard to change even if the facet coating film remarkably generates heat. Further, the nitrogen-containing film is formed between the cavity facet and the oxide film in contact with the cavity facet, whereby diffusion of oxygen from the external atmosphere into the cavity facet can be suppressed. Thus, the interface between the cavity facet and the facet coating film is hard to deteriorate. Consequently, the semiconductor laser device according to the first aspect of the present invention can be improved in reliability.

In this case, the oxide film preferably has a composition of Hf_{0.3}Si_{0.15}O_{0.55} or Hf_{0.15}Al_{0.35}O_{0.5}. According to this structure, a stable oxide film having a high crystallization temperature can be formed.

In the aforementioned semiconductor laser device according to the first aspect, the nitrogen-containing film is preferably a nitride film containing an element, i.e., at least either Si or Al, contained in the oxide film. According to this structure, the oxide film and the nitride film constituting the facet coating film contain the common element, whereby adhesiveness therebetween is improved. Thus, separation of the facet coating film can be suppressed.

In the aforementioned semiconductor laser device according to the first aspect, the nitrogen-containing film preferably includes a first oxynitride film, in contact with the cavity facet, between the cavity facet and the oxide film. According to this structure, diffusion of oxygen from the external atmosphere into the cavity facet can be easily suppressed through the first oxynitride film serving as the nitrogen-containing film.

In the aforementioned structure having the nitrogen-containing film including the first oxynitride film, the first oxynitride film preferably contains an element, i.e., at least either Si or Al, contained in the oxide film. According to this structure, adhesiveness between the oxide film and the first oxynitride film in the facet coating film can be easily improved. This, separation of the facet coating film can be suppressed.

In the aforementioned semiconductor laser device according to the first aspect, the facet coating film preferably further has a second oxynitride film arranged between the oxide film and the nitrogen-containing film. According to this structure, adhesiveness on the interface between the oxide film and the second oxynitride film and that on the interface between the second oxynitride film and the nitrogen-containing film can both be improved. Thus, separation of the facet coating film can be suppressed.

In the aforementioned structure provided with the facet coating film further having the second oxynitride film, the second oxynitride film preferably contains an element, i.e., at least either Si or Al, contained in the oxide film. According to this structure, the adhesiveness between the oxide film and the second oxynitride film in the facet coating film can be easily improved.

In the aforementioned semiconductor laser device according to the first aspect, the cavity facet preferably includes a light-emitting surface and a light-reflecting surface, and the facet coating film is preferably arranged on the light-emitting surface. In the present invention, the “light-emitting surface” and the “light-reflecting surface” are distinguished from each other with respect to a pair of cavity facets formed on the semiconductor laser device, in response to the large-small relation between the light intensity levels of laser beams emitted from the respective facets. In other words, the cavity facet emitting a laser beam having relatively large light intensity corresponds to the light-emitting surface, and the cavity facet emitting a laser beam having relatively small light intensity corresponds to the light-reflecting surface. According to this structure, the aforementioned facet coating film is formed on the light-emitting surface serving as a principal laser beam emitting surface, whereby deterioration of the light-emitting surface can be reliably suppressed.

In the aforementioned semiconductor laser device according to the first aspect, the cavity facet preferably includes a light-emitting surface and a light-reflecting surface, the facet coating film is preferably arranged on the light-reflecting surface, the facet coating film preferably further has a first reflectance control film controlling reflectance of the light-reflecting surface, and the first reflectance control film is preferably arranged on a surface of the facet coating film opposite to the light-reflecting surface. In the present invention, the “reflectance control film” denotes a wide concept indicating a film substantially reflecting a laser beam. According to this structure, deterioration of not only the light-emitting surface but also the light-reflecting surface can be reliably suppressed. Further, the light-reflecting surface can obtain desired reflectance due to the first reflectance control film formed thereon.

In the aforementioned structure provided with the facet coating film further having the first reflectance control film, the first reflectance control film preferably includes a film of an oxide in contact with the oxide film. According to this structure, the adhesiveness between the oxide film and the first reflectance control film in the facet coating film formed on the light-reflecting surface can be improved.

In this case, the film of the oxide is preferably made of a silicon oxide. According to this structure, the oxide film and the film of the oxide in the facet coating film contain the common Si element, whereby the adhesiveness between the oxide film and the film of the oxide can be easily improved.

In the aforementioned structure provided with the facet coating film further having the first reflectance control film, the first reflectance control film preferably consists of a multilayer film having a high refractive index film and a low refractive index film alternately stacked with each other, and the high refractive index film is preferably arranged on a surface of the first reflectance control film opposite to the light-reflecting surface. In the present invention, a dielectric film having a relatively large refractive index corresponds to the “high refractive index film” and a dielectric film having a relatively small refractive index corresponds to the “low refractive index film” in two types of dielectric films constituting the first reflectance control film. According to this structure, desired reflectance can be reliably obtained through the high refractive index film.

Preferably in the aforementioned semiconductor laser device according to the first aspect having a relation of t1<λ/(4×n1), t2<λ/(4×n2) and t1<t2, where λ, n1, n2, t1 and t2 represent the wavelength of a laser beam emitted from the active layer, the refractive index of the oxide film, the refractive index of the nitrogen-containing film, the thickness of the oxide film and the thickness of the nitrogen-containing film respectively. According to this structure, the laser beam emitted from the cavity facet can be transmitted through the nitrogen-containing film with no influence by the thickness thereof, to reach the oxide film. Consequently, the nitrogen-containing film can easily be inhibited from influencing the reflectance control function of the oxide film set to have desired reflectance. Further, the thickness of the nitrogen-containing film is so small that separation or the like resulting from stress after the formation of the facet coating film can also be suppressed.

Preferably in the aforementioned semiconductor laser device according to the first aspect having a relation of w+x1≦y+z or w+x2≦y+z, where w, x1, x2, y and z (w>0, x1≧0, x2≧0, y>0 and z≧0, at least either x1 or x2 is nonzero) represent the atomic number ratios of Hf, Si, Al, oxygen and nitrogen in the facet coating film respectively. According to this structure, the resistivity of the oxide film can be so increased that various layers constituting the semiconductor element layer, a surface electrode and a rear electrode can be easily insulated from each other also when the facet coating film is formed on the cavity facet.

A semiconductor laser device according to a second aspect of the present invention includes a semiconductor element layer having an active layer and a cavity facet and a facet coating film arranged on the cavity facet, while the facet coating film includes an oxide film made of hafnium silicate (HfSiO) containing nitrogen or hafnium aluminate (HfAlO) containing nitrogen, and the oxide film is in contact with the cavity facet.

In the semiconductor laser device according to the second aspect of the present invention, as hereinabove described, the facet coating film formed on the cavity facet has the oxide film made of HfSiO or HfAlO. The oxide film of such a material has a crystallization temperature of at least 1000° C. and is superior in thermal stability as compared with HfO₂, whereby optical characteristics are hard to change even if the facet coating film remarkably generates heat. Further, the oxide film contains nitrogen and is in contact with the cavity facet, whereby diffusion of oxygen from the external atmosphere into the cavity facet can be suppressed. Thus, the interface between the cavity facet and the facet coating film is hard to deteriorate. Consequently, the semiconductor laser device according to the second aspect of the present invention can be improved in reliability.

In this case, the oxide film, containing nitrogen, of HfSiO or HfAlO preferably has a composition of Hf_{0.3}Si_{0.15}O_{0.25}N_{0.3} or Hf_{0.15}Al_{0.35}O_{0.3}N_{0.2}. According to this structure, a stable oxide film having a high crystallization temperature can be formed, and diffusion of oxygen from the external atmosphere can also be suppressed.

In the aforementioned semiconductor laser device according to the second aspect, the cavity facet preferably includes a light-emitting surface and a light-reflecting surface, and the facet coating film is preferably arranged on the light-emitting surface. According to this structure, the aforementioned facet coating film is formed on the light-emitting surface serving as a principal laser beam emitting surface, whereby deterioration of the light-emitting surface can be reliably suppressed.

In the aforementioned semiconductor laser device according to the second aspect, the cavity facet preferably includes a light-emitting surface and a light-reflecting surface, the facet coating film is preferably arranged on the light-reflecting surface, the facet coating film preferably further has a second reflectance control film controlling reflectance of the light-reflecting surface, the second reflectance control film is preferably arranged on a surface of the oxide film opposite to the light-reflecting surface, and the second reflectance control film preferably contains an element, i.e., at least either Si or Al, contained in the oxide film. According to this structure, desired reflectance can be obtained through the second reflectance control film. At this time, further, adhesiveness between the oxide film and the second reflectance control film in the facet coating film can be easily improved.

In the aforementioned semiconductor laser device according to the second aspect, the cavity facet preferably includes a light-emitting surface and a light-reflecting surface, the facet coating film is preferably arranged on the light-reflecting surface, the facet coating film preferably further has a third reflectance control film controlling reflectance of the light-reflecting surface, the third reflectance control film is preferably arranged on a surface of the oxide film opposite to the light-reflecting surface, the third reflectance control film preferably consists of a multilayer film having a high refractive index film and a low refractive index film alternately stacked with each other, and the high refractive index film is preferably arranged on a surface of the third reflectance control film opposite to the light-reflecting surface. According to this structure, desired reflectance can be reliably obtained through the high refractive index film.

Preferably in the aforementioned semiconductor laser device according to the second aspect having a relation of w+x1≦y+z or w+x2≦y+z, where w, x1, x2, y and z (w>0, x1≧0, x2≧0, y>0 and z≧0, at least either x1 or x2 is nonzero) represent the atomic number ratios of Hf, Si, Al, oxygen and nitrogen in the oxide film containing nitrogen respectively. According to this structure, the resistivity of the oxide film can be so increased that various layers constituting the semiconductor element layer, a surface electrode and a rear electrode can be easily insulated from each other also when the facet coating film is formed on the cavity facet.

In the aforementioned semiconductor laser device according to the first aspect, the semiconductor element layer is preferably made of a nitride-based semiconductor. According to this structure, the semiconductor element layer and the aforementioned nitrogen-containing film formed on the cavity facet identically contain nitrogen, whereby the semiconductor laser device in which the adhesiveness between the facet coating film and the semiconductor element layer is improved can be easily obtained.

An optical apparatus according to a third aspect of the present invention includes a semiconductor laser device including a semiconductor element layer provided with an active layer and a cavity facet and a facet coating film arranged on the cavity facet and an optical system adjusting a laser beam emitted from the semiconductor laser device, while the facet coating film has an oxide film made of hafnium silicate (HfSiO) or hafnium aluminate (HfAlO), the facet coating film further has a nitrogen-containing film, in contact with the cavity facet, between the cavity facet and the oxide film, or the oxide film further contains nitrogen, and is in contact with the cavity facet.

In the optical apparatus according to the third aspect of the present invention, as hereinabove described, the semiconductor laser device includes the facet coating film, having the oxide film made of hafnium silicate (HfSiO) or hafnium aluminate (HfAlO), on the cavity facet. The oxide film of such a material has a crystallization temperature of at least 1000° C. and is superior in thermal stability as compared with HfO₂, whereby optical characteristics are hard to change even if the facet coating film remarkably generates heat. Further, the nitrogen-containing film is formed between the cavity facet and the oxide film in contact with the cavity facet or the oxide contains nitrogen and is in contact with the cavity facet, whereby diffusion of oxygen from the external atmosphere into the cavity facet can be suppressed. Thus, the interface between the cavity facet and the facet coating film is hard to deteriorate. Consequently, the semiconductor laser device can be improved in reliability, whereby the optical apparatus can be improved in reliability also when the wavelength of a laser beam is shortened and the output thereof is increased.

According to the present invention, a semiconductor laser device and an optical apparatus each improvable in reliability can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view of a semiconductor laser device according to a first embodiment of the present invention in a state cut parallelly to a cavity direction;

FIG. 2 is a longitudinal sectional view of a semiconductor laser device according to a second embodiment of the present invention in a state cut parallelly to a cavity direction;

FIG. 3 is a longitudinal sectional view of a nitride-based semiconductor laser device according to Example 1 the present invention in a state cut perpendicularly to a cavity direction;

FIG. 4 is a longitudinal sectional view of a nitride-based semiconductor laser device according to Example 4 the present invention in a state cut parallelly to a cavity direction;

FIG. 5 is a perspective view showing the appearance of a laser unit according to a third embodiment of the present invention;

FIG. 6 is a top plan view of the laser unit according to the third embodiment of the present invention in a state where a lid body of a can package is removed; and

FIG. 7 is a block diagram of an optical apparatus according to a fourth embodiment of the present invention.

### DESCRIPTION OF THE PREFERRED EMBODIMENTS

Embodiments of the present invention are now described with reference to the drawings.

### First Embodiment

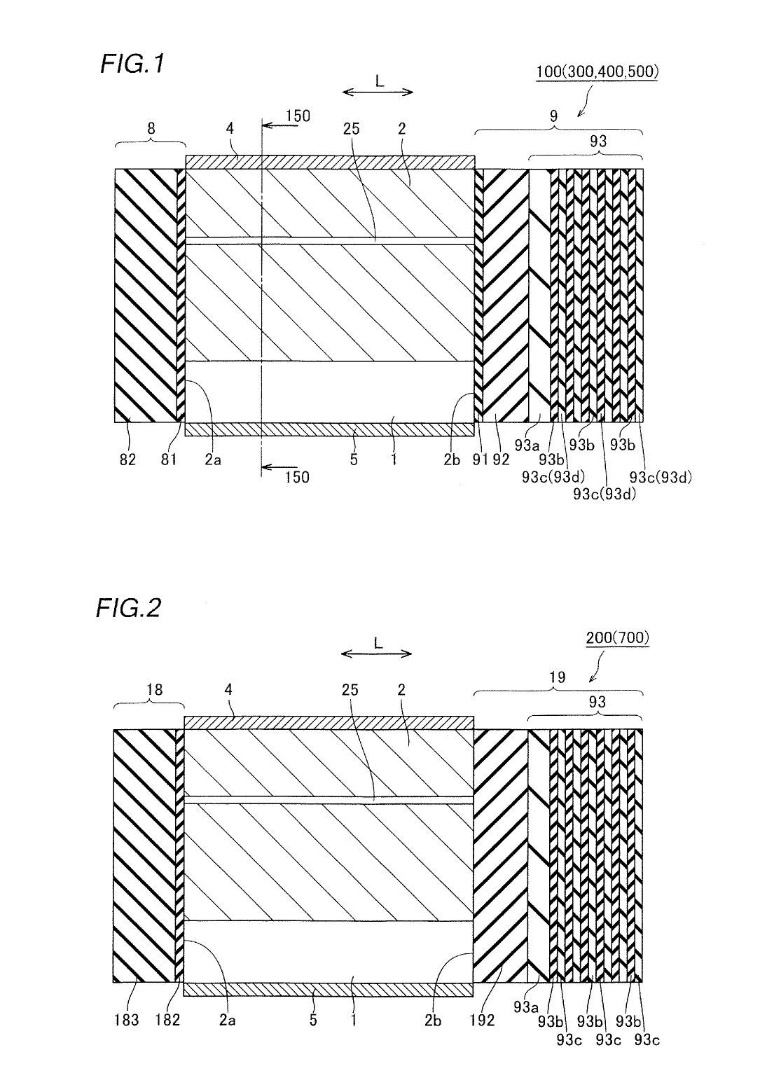

First, the structure of a semiconductor laser device 100 according to a first embodiment of the present invention is described with reference to FIG. 1.

In the semiconductor laser device 100 according to the first embodiment of the present invention, a semiconductor element layer 2 consisting of a plurality of semiconductor layers including an active layer 25 is formed on the upper surface of a substrate 1 of a semiconductor, as shown in FIG. 1. A surface electrode 4 and a rear electrode 5 are formed on the upper surface and the lower surface of the substrate 1 respectively. Cavity facets 2a and 2b are formed on the semiconductor element layer 2 in the extensional direction (direction L) of a cavity, and facet coating films 8 and 9 are formed on the cavity facets 2a and 2b respectively. The cavity facets 2a and 2b are examples of the “light-emitting surface” and the “light-reflecting surface” in the present invention respectively.

According to the first embodiment, the facet coating film 8 provided on the cavity facet 2a is constituted of a nitride film 81 formed to be in contact with the cavity facet 2a and an oxide film 82 of hafnium silicate (HfSiO) or hafnium aluminate (HfAlO) formed on the surface of the nitride film 81 opposite to the cavity facet 2a. The facet coating film 9 provided on the cavity facet 2b is constituted of a nitride film 91 formed to be in contact with the cavity facet 2b, an oxide film 92 of hafnium silicate (HfSiO) or hafnium aluminate (HfAlO) formed on the surface of the nitride film 91 opposite to the cavity facet 2b and a multilayer reflecting film 93 consisting of a plurality of dielectric films. The nitride films 81 and 91 are examples of the “nitrogen-containing film” in the present invention. The multilayer reflecting film 93 is an example of the “first reflectance control film” in the present invention.

In the semiconductor laser device 100 according to the first embodiment, as hereinabove described, the facet coating films 8 and 9 provided on the cavity facets 2a and 2b have the oxide films 82 and 92 of HfSiO or HfAlO respectively. The oxide films 82 and 92 of such a material have a crystallization temperature of at least 1000° C. and are superior in thermal stability as compared with HfO₂, whereby optical characteristics are hard to change even if the facet coating films 8 and 9 remarkably generate heat. Further, the nitride film 81 is formed between the cavity facet 2a and the oxide film 82 to be in contact with the cavity facet 2a while the nitride film 91 is formed between the cavity facet 2b and the oxide film 92 to be in contact with the cavity facet 2b. Thus, diffusion of oxygen from the external atmosphere into the cavity facets 2a and 2b can be suppressed. Therefore, the interfaces between the cavity facets 2a and 2b and the facet coating films 8 and 9 are hard to deteriorate. Consequently, the semiconductor laser device 100 can be improved in reliability.

### Second Embodiment

The structure of a semiconductor laser device 200 according to a second embodiment of the present invention is now described with reference to FIG. 2.

In the semiconductor laser device 200 according to the second embodiment of the present invention, a facet coating film 18 provided on a cavity facet 2a is constituted of an oxide film 182 of HfSiO or HfAlO containing nitrogen formed to be in contact with the cavity facet 2a and a reflectance control film 183 consisting of a dielectric film formed on the surface of the oxide film 182 opposite to the cavity facet 2a, as shown in FIG. 2. A facet coating film 19 provided on a cavity facet 2b is constituted of an oxide film 192 of HfSiO or HfAlO containing nitrogen formed to be in contact with the cavity facet 2b and a multilayer reflecting film 93 consisting of a plurality of dielectric films. The reflectance control film 93 is an example of the “second reflectance control film” and an example of the “third reflectance control film” in the present invention.

The remaining structure of the semiconductor laser device 200 according to the second embodiment is similar to that of the semiconductor laser device 100 according to the aforementioned first embodiment.

In the semiconductor laser device 200 according to the second embodiment, as hereinabove described, the facet coating films 18 and 19 provided on the cavity facets 2a and 2b have the oxide films 182 and 192 of HfSiO or HfAlO respectively. The oxide films 182 and 192 of such a material have a crystallization temperature of at least 1000° C. and are superior in thermal stability as compared with HfO₂, whereby optical characteristics are hard to change even if the facet coating films 18 and 19 remarkably generate heat. Further, the oxide films 182 and 192 contain nitrogen, whereby diffusion of oxygen from the external atmosphere into the cavity facets 2a and 2b can be suppressed. Thus, the interfaces between the cavity facets 2a and 2b and the facet coating films 18 and 19 are hard to deteriorate. Consequently, the semiconductor laser device 200 can be improved in reliability.

In each of the semiconductor laser devices 100 and 200 according to the aforementioned first and second embodiments, the reflectance on the side of the cavity facet 2b can be increased with respect to a laser beam emitted from the active layer 25 in the direction L mainly by forming the multilayer reflecting film 93. On the other hand, the reflectance on the side of the cavity facet 2a can be reduced by controlling the thicknesses and the refractive indices of the nitride film 81 and the oxide film 82 in the semiconductor laser device 100 or by controlling the thicknesses and the refractive indices of the oxide film 182 and the reflectance control film 183 in the semiconductor laser device 100. Thus, the reflectance on the side of the cavity facet 2b with respect to the laser beam emitted from the active layer 25 in the direction L is set larger than that on the side of the cavity facet 2a in each of the semiconductor laser devices 100 and 200. Consequently, the intensity of the laser beam emitted from the cavity facet 2a is larger than that of the laser beam emitted from the cavity facet 2b, whereby side facets on the sides of the cavity facets 2a and 2b function as a light-emitting surface (front facet) and a light-reflecting surface (rear facet) respectively.

### EXAMPLE 1

The specific structure of a semiconductor laser device having a structure similar to that of the semiconductor laser device 100 according to the aforementioned first embodiment is now described.

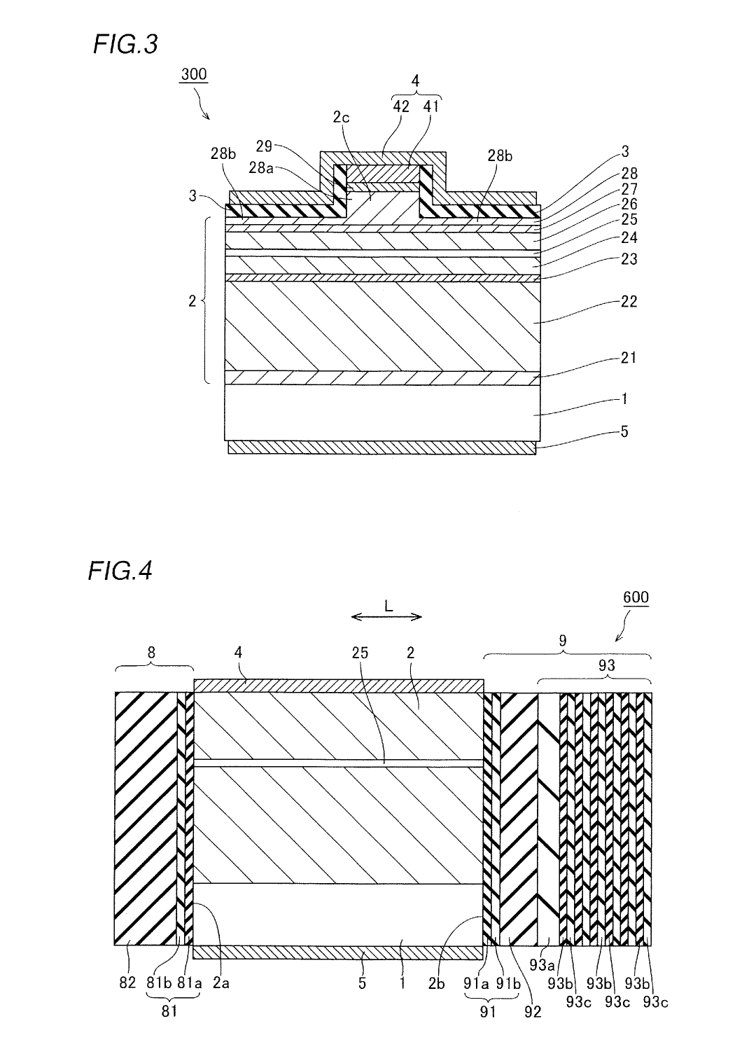

The structure of a nitride-based semiconductor laser device 300 according to Example 1 of the present invention is described with reference to FIGS. 1 and 3. FIG. 3 is a sectional view taken along the line 150-150 in FIG. 1, showing a section orthogonal to the extensional direction (direction L: [1-100] direction) of a cavity.

First, the structures of facet coating films 8 and 9 of the nitride-based semiconductor laser device 300 according to Example 1 of the present invention are described with reference to FIG. 1. In the nitride-based semiconductor laser device 300, a nitride film 81 and an oxide film 8 constituting the facet coating film 8 provided on a cavity facet 2a consist of an AlN film (refractive index n2: about 2.10) having a thickness t2 of about 10 nm and an HfSiO film (refractive index n1: about 1.85) having a thickness t1 of about 70 nm.

On the other hand, a nitride film 91 and an oxide film 92 constituting the facet coating film 9 provided on a cavity facet 2b consist of an AlN film (refractive index n22: about 2.10) having a thickness t22 of about 10 nm and an HfSiO film (refractive index n11: about 1.85) having a thickness t11 of about 80 nm. A multilayer reflecting film 93 has a structure obtained by alternately stacking six SiO₂ layers 93b (refractive index: about 1.46) each having a thickness of about 70 nm and six ZrO₂ layers 93c (refractive index: about 2.13) each having a thickness of about 48 nm on an SiO₂ layer 93a (refractive index: about 1.46), having a thickness of about 140 nm, formed to be in contact with the oxide film 92 so that the final ZrO₂ layer 93c is arranged on the outermost surface. The SiO₂ layer 93a is an example of the “film of an oxide” in the present invention, while the SiO₂ layers 93b and the ZrO₂ layers 93c are examples of the “low refractive index film” and the “high refractive index film” in the present invention respectively.

In the nitride-based semiconductor laser device 300 according to Example 1, cleavage planes formed by cleaving a semiconductor element layer 2 are employed as the cavity facets 2a and 2b, and layers constituting the facet coating films 8 and 9 are successively formed on the cavity facets 2a and 2b by electron cyclotron resonance (ECR) sputtering.

The facet coating films 8 and 9 having the aforementioned structures are so formed that the reflectance values on the sides of the cavity facets 2a and 2b with respect to a laser beam having a wavelength of about 405 nm are about 8% and about 98% respectively. In the nitride-based semiconductor laser device 300 according to Example 1, side facets on the sides of the cavity facets 2a and 2b function as a light-emitting surface (front facet) and a light-reflecting surface (rear facet) respectively.

The structure of the nitride-based semiconductor laser device 300 in the stacking direction is now described with reference to FIG. 3.

In the nitride-based semiconductor laser device 300, a substrate 1 of n-type GaN doped with oxygen has a thickness of about 100 μm, and a semiconductor element layer 2 consisting of a plurality of nitride-based semiconductor layers including an active layer 25 as well as a current blocking layer 3 and a surface electrode (p-side electrode) 4 formed on the semiconductor element layer 2 are provided on the upper surface ((0001) plane) of the substrate 1. A rear electrode (n-side electrode) 5 is formed on the lower surface ((000-1) plane) of the substrate 1. In appearance, the nitride-based semiconductor laser device 300 has a length (cavity length) of about 800 μm, a width of about 200 μm and a thickness of about 120 μm.

The semiconductor element layer 2 is formed by stacking an underlayer 21 of n-type GaN having a thickness of about 0.1 μm, an n-type cladding layer 22 of n-type Al_{0.07}Ga_{0.93}N having a thickness of about 0.4 μm, a carrier blocking layer 23 of n-type Al_{0.16}Ga_{0.84}N having a thickness of about 5 nm, an n-side optical guiding layer 24 of undoped GaN having a thickness of about 0.1 μm, the active layer 25 having a multiple quantum well structure obtained by stacking a plurality of barrier layers of InGaN and a plurality of well layers of InGaN, a p-side optical guiding layer 26 of p-type GaN having a thickness of about 0.1 μm, a cap layer 27 of p-type Al_{0.16}Ga_{0.84}N having a thickness of about 20 nm, a p-type cladding layer 28 of p-type Al_{0.07}Ga_{0.93}N and a contact layer 29 of p-type In_{0.02}Ga_{0.98}N having a thickness of about 10 nm in this order from the side of the substrate 1.

Each of the underlayer 21, the n-type cladding layer 22 and the n-type carrier blocking layer 23 is doped with Ge of about 5×10¹⁸ cm⁻³. On the other hand, each of the p-side optical guiding layer 26, the cap layer 27, the p-type cladding layer 28 and the contact layer 29 is doped with Mg of about 4×10¹⁹ cm⁻³.

The active layer 25 has the MQW structure obtained by alternately stacking four barrier layers of In_{0.02}Ga_{0.98}N each having a thickness of about 20 nm and three well layers of In_{0.1}Ga_{0.9}N each having a thickness of about 3 nm. All of the barrier layers and the well layers constituting the active layer 25 are undoped.

The p-type cladding layer 28 is constituted of a projecting portion 28a, having a width of about 1.5 μm, extending in the direction L in a striped manner and planar portions 28b, each having a thickness of about 80 nm, provided on both sides of the projecting portion 28a. The thickness of the p-type cladding layer 28 in the projecting portion 28a is about 0.4 μm. The contact layer 29 is formed only on the upper surface of the projecting portion 28a. The projecting portion 28a of the p-type cladding layer 28 and the contact layer 29 form a ridge portion 2c extending in the direction L in a striped manner on the upper surface of the semiconductor element layer 2. The ridge portion 2c constitutes a current injection portion, while a waveguide extending in the direction L in a striped manner along the ridge portion 2c is formed in a region, including the active layer 25, located under the ridge portion 2c.

The current blocking layer 3 of SiO₂ having a thickness of about 0.3 μm is formed on the side surfaces of the projecting portion 28a of the p-type cladding layer 28 and the upper surfaces of the planar portions 28b thereof, to expose the upper surface of the ridge portion 2c (upper surface of the contact layer 29).

The surface electrode (p-side electrode) 4 is constituted of an ohmic electrode layer 41 formed to be in contact with the upper surface of the ridge portion 2c and a p-side pad electrode 42 formed on the ohmic electrode layer 41 and the current blocking layer 3. In the ohmic electrode layer 41, a Pt layer having a thickness of about 5 nm, a Pd layer having a thickness of about 100 nm and an Au layer having a thickness of about 150 nm are stacked in this order from the side of the contact layer 29. In the p-side pad electrode 42, a Ti layer having a thickness of about 0.1 μm, a Pd layer having a thickness of about 0.1 μm and an Au layer having a thickness of about 3 μm are stacked in this order from the side of the ohmic electrode layer 41 and the current blocking layer 3.

In the rear electrode (n-side electrode) 5, an Al layer having a thickness of about 10 nm, a Pt layer having a thickness of about 20 nm and an Au layer having a thickness of about 300 nm are stacked in this order from the side of the substrate 1. The nitride-based semiconductor laser device 300 having a lasing wavelength λ of about 405 nm is constituted in the aforementioned manner.

In the nitride-based semiconductor laser device 300, as hereinabove described, the facet coating films 8 and 9 provided on the cavity facets 2a and 2b have the oxide films 82 and 92 of HfSiO respectively. The oxide films 82 and 92 of such a material have a crystallization temperature of at least 1000° C. and are superior in thermal stability as compared with HfO₂, whereby optical characteristics are hard to change even if the facet coating films 8 and 9 remarkably generate heat. Further, the nitride films 81 and 91 of AlN are formed between the cavity facets 2a and 2b and the oxide films 82 and 92 to be in contact with the cavity facets 2a and 2b respectively, whereby diffusion of oxygen from the external atmosphere into the cavity facets 2a and 2b can be suppressed. Thus, the interfaces between the cavity facets 2a and 2b and the facet coating films 8 and 9 are hard to deteriorate. Consequently, the semiconductor laser device 300 can be improved in reliability.

In the nitride-based semiconductor laser device 300, as hereinabove described, the multiplayer reflecting film 93 includes the SiO₂ layer 93a formed to be in contact with the oxide film 92 so that the oxide film 92 (HfSiO) and the SiO₂ layer 93a contain the common Si element, whereby the adhesiveness between the oxide film 92 and the SiO₂ layer 93a can be easily improved.

In the nitride-based semiconductor laser device 300, as hereinabove described, the ZrO₂ layer 93c which is a high refractive index film is arranged on a surface of the multilayer reflecting film 93 opposite to the cavity facet 2b, whereby desired reflectance can be reliably obtained through the high refractive index film arranged on the outermost surface.

As hereinabove described, the nitride-based semiconductor laser device 300 has the relations t1<λ/(4×n1), t2<λ/(4×n2) and t1<t2 on the side of the facet coating film 8 and the relations t11<λ/(4×n11), t22<λ/(4×n22) and t11<t22 on the side of the facet coating film 9 between the wavelength of the laser beam and the refractive indices and the thicknesses of the oxide films 82 and 92 and the nitride films 81 and 91 constituting the facet coating films 8 and 9. Thus, laser beams emitted from the cavity facets 2a and 2b can be transmitted through the nitride films 81 and 91 with no influence by the thicknesses thereof to reach the oxide films 82 and 92 in the facet coating films 8 and 9 respectively. Consequently, the nitride films 81 and 91 can easily be inhibited from influencing the reflectance control functions of the oxide films 82 and 92 set to have desired reflectance values. Further, the thicknesses of the nitride films 81 and 91 are so small that separation or the like resulting from stress after the formation of the facet coating films 8 and 9 can also be suppressed.

In the nitride-based semiconductor laser device 300, the thicknesses of the nitride films 81 and 91 are preferably in the range of at least about 5 nm and not more than about 20 nm. According to this structure, separation or the like of the facet coating films 8 and 9 resulting from stress can be suppressed, while diffusion of oxygen from the external atmosphere can also be suppressed. The thicknesses of the oxide films 82 and 92 are preferably in the range of at least about 60 nm and not more than about 200 nm. According to this structure, the reflectance on the side of the cavity facet 2a can be easily controlled to a desired value.

In the nitride-based semiconductor laser device 300, as hereinabove described, the nitride films 81 and 91 identically containing nitrogen are formed on the semiconductor element layer 2 of the nitride-based semiconductor to be in contact therewith, whereby the adhesiveness of the facet coating films 8 and 9 can be further improved.

### EXAMPLE 2

A nitride-based semiconductor laser device 400 according to Example 2 of the present invention also has a structure similar to that of the semiconductor laser device 100 according to the aforementioned first embodiment.

Referring to FIG. 1, an oxide film 92 constituting a facet coating film 9 provided on a cavity facet 2b consists of an HfSiO film (refractive index n11: about 1.85) having a thickness t11 of about 68 nm while a multilayer reflecting film 93 has a structure obtained by alternately stacking seven SiO₂ layers 93b (refractive index: about 1.46) each having a thickness of about 80 nm and seven HfO₂ layers 93d (refractive index: about 1.95) each having a thickness of about 35 nm on an SiO₂ layer 93c (refractive index: about 1.46), having a thickness of about 140 nm, formed to be in contact with the oxide film 92 so that the final HfO₂ layer 93d is arranged on the outermost surface in the nitride-based semiconductor laser device 400 according to Example 2 of the present invention. The HfO₂ layers 93d are examples of the “high refractive index film” in the present invention. The remaining structures of the facet coating film 9 and another facet coating film 8 of the nitride-based semiconductor laser device 400 according to Example 2 are similar to the remaining structures of the facet coating films 9 and 8 of the nitride-based semiconductor laser device 300 according to Example 1.

The facet coating films 8 and 9 having the aforementioned structures are so formed that the reflectance values on the sides of another cavity facet 2a and the cavity facet 2b with respect to a laser beam having a wavelength of about 405 nm are about 8% and about 95% respectively. In the nitride-based semiconductor laser device 400 according to Example 2, side facets on the sides of the cavity facets 2a and 2b function as a light-emitting surface (front facet) and a light-reflecting surface (rear facet) respectively.

In a semiconductor element layer 2, an n-type cladding layer 22 consists of an n-type Al_{0.1}Ga_{0.9}N layer having a thickness of about 0.7 μm, a carrier blocking layer 23 consists of an undoped Al_{0.2}Ga_{0.8}N layer having a thickness of about 10 nm, and an n-side optical guiding layer 24 consists of an n-type Al_{0.03}Ga_{0.97}N layer having a thickness of about 0.15 μm. An active layer 25 has a structure obtained by alternately stacking two barrier layers of Al_{0.06}Ga_{0.94}N each having a thickness of about 10 nm and a well layer of GaN having a thickness of about 18 nm. A p-side optical guiding layer 26 consists of a p-type Al_{0.03}Ga_{0.97}N layer having a thickness of about 0.15 μm, a cap layer 27 consists of an undoped Al_{0.2}Ga_{0.8}N layer having a thickness of about 10 nm, and a p-type cladding layer 28 is made of p-type Al_{0.1}Ga_{0.9}N. The n-side optical guiding layer 24 is doped with Ge of about 5×10¹⁸ cm⁻³, while each of the p-side optical guiding layer 26 and the p-type cladding layer 28 is doped with Mg of about 3×10¹⁹ cm⁻³.

The remaining structure of the semiconductor element layer 2 of the nitride-based semiconductor laser device 400 according to Example 2 is similar to the remaining structure of the semiconductor element layer 2 of the nitride-based semiconductor laser device 300 according to Example 1. The nitride-based semiconductor laser device 400 having a lasing wavelength λ of about 405 nm is constituted in the aforementioned manner.

In the nitride-based semiconductor laser device 400, as hereinabove described, the HfO₂ layers 93d having smaller light absorption in the ultraviolet region are employed in the multilayer reflecting film 93 of the facet coating film 9, in place of the ZrO₂ layers 93c employed in the nitride-based semiconductor laser device 300 according to Example 1. Thus, a laser beam in the ultraviolet region can be efficiently extracted. The remaining effects of Example 2 are similar to those of Example 1.

### EXAMPLE 3

A nitride-based semiconductor laser device 500 according to Example 3 of the present invention also has a structure similar to that of the semiconductor laser device 100 according to the aforementioned first embodiment.

Referring to FIG. 1, a nitride film 81 constituting a facet coating film 8 provided on a cavity facet 2a consists of a nitrogen-containing HfSiO film (HfSiON film which is substantially an oxynitride film, refractive index n2: about 2.00) having a thickness t2 of about 10 nm while an oxide film 82 consists of an HfSiO film (refractive index n1: about 1.85) having a thickness t1 of about 68 nm in the nitride-based semiconductor laser device 500 according to Example 3 of the present invention. A nitride film 91 constituting a facet coating film 9 provided on a cavity facet 2b consists of a nitrogen-containing HfSiO film (HfSiON film which is substantially an oxynitride film, refractive index n22: about 2.10) having a thickness t22 of about 10 nm. The HfSiON films constituting the nitride films 81 and 91 are examples of the “first oxynitride film” in the present invention respectively. The remaining structures of the facet coating films 8 and 9 of the nitride-based semiconductor laser device 500 according to Example 3 are similar to the remaining structures of the facet coating films 8 and 9 of the nitride-based semiconductor laser device 300 according to Example 1.

The facet coating films 8 and 9 having the aforementioned structures are so formed that reflectance values on the sides of the cavity facets 2a and 2b with respect to a laser beam having a wavelength of about 405 nm are about 8% and about 98% respectively. In the nitride-based semiconductor laser device 500 according to Example 3, side facets on the sides of the cavity facets 2a and 2b function as a light-emitting surface (front facet) and a light-reflecting surface (rear facet) respectively.

The structure of a semiconductor element layer 2 of the nitride-based semiconductor laser device 500 according to Example 3 is similar to that of the semiconductor element layer 2 of the nitride-based semiconductor laser device 300 according to Example 1. The nitride-based semiconductor laser device 500 having a lasing wavelength λ of about 405 nm is constituted in the aforementioned manner.

In the nitride-based semiconductor laser device 500, as hereinabove described, the nitride film 81 contains Si contained in the oxide film 82 while the nitride film 91 contains Si contained in the oxide film 92, whereby the adhesiveness between the oxide film 82 and the nitride film 81 and that between the oxide film 92 and the nitride film 91 are improved in the facet coating films 8 and 9 respectively. Thus, separation of the facet coating films 8 and 9 can be suppressed.

In the nitride-based semiconductor laser device 500, as hereinabove described, the nitride films 81 and 91 are constituted of the HfSiON films, whereby diffusion of oxygen from the external atmosphere into the cavity facets 2a and 2b can be easily suppressed through the nitrogen-containing HfSiON films. The remaining effects of Example 3 are similar to those of Example 1.

### EXAMPLE 4

A nitride-based semiconductor laser device 600 according to Example 4 of the present invention also has a structure similar to that of the semiconductor laser device 100 according to the aforementioned first embodiment.

Referring to FIG. 4, a nitride film 81 constituting a facet coating film 8 provided on a cavity facet 2a has a multilayer structure of an AlN film 81a (refractive index: about 2.10), having a thickness of about 10 nm, formed to be in contact with the cavity facet 2a and a nitrogen-containing HfSiO film 81b (HfSiON film which is substantially an oxynitride film, refractive index: about 2.00), having a thickness of about 69 nm, formed on the AlN film 81a in the nitride-based semiconductor laser device 600 according to Example 4 of the present invention. The nitride film 81 has a thickness t2 of about 79 nm and an average refractive index n2 of about 2.00.

A nitride film 91 constituting a facet coating film 9 provided on a cavity facet 2b has a multilayer structure of an AlN film 91a (refractive index: about 2.10), having a thickness of about 10 nm, formed to be in contact with the cavity facet 2b and a nitrogen-containing HfSiO film 91b (HfSiON film which is substantially an oxynitride film, refractive index: about 2.00), having a thickness of about 30 nm, formed on the AlN film 91a. The nitride film 91 has a total thickness t22 of about 40 nm and an average refractive index n22 of about 2.10. The HfSiON films constituting the nitride films 81 and 91 are examples of the “second oxynitride film” in the present invention respectively. The remaining structures of the facet coating films 8 and 9 of the nitride-based semiconductor laser device 600 according to Example 4 are similar to the remaining structures of the facet coating films 8 and 9 of the nitride-based semiconductor laser device 300 according to Example 1.

The facet coating films 8 and 9 having the aforementioned structures are so formed that reflectance values on the sides of the cavity facets 2a and 2b with respect to a laser beam having a wavelength of about 405 nm are about 8% and about 98% respectively. In the nitride-based semiconductor laser device 600 according to Example 4, side facets on the sides of the cavity facets 2a and 2b function as a light-emitting surface (front facet) and a light-reflecting surface (rear facet) respectively.

The structure of a semiconductor element layer 2 of the nitride-based semiconductor laser device 600 according to Example 4 is similar to that of the semiconductor element layer 2 of the nitride-based semiconductor laser device 300 according to Example 1. The nitride-based semiconductor laser device 600 having a lasing wavelength λ of about 405 nm is constituted in the aforementioned manner.

In the nitride-based semiconductor laser device 600, as hereinabove described, the nitride films 81 and 91 provided on the oxide films 82 and 92 contain Hf, Si and O in common with the oxide films 82 and 92, whereby the adhesiveness between the oxide film 82 and the nitride film 81 and that between the oxide film 92 and the nitride film 91 are improved in the facet coating films 8 and 9 respectively. Further, the AlN films and the HfSiON films which are oxynitride films contain nitrogen in common with each other in the nitride films 81 and 91, whereby the adhesiveness is improved also on the interfaces between the AlN films and the HfSiON films. Thus, separation of the facet coating films 8 and 9 can be suppressed. The remaining effects of Example 4 are similar to those of Example 1.

### EXAMPLE 5

A nitride-based semiconductor laser device 700 according to Example 5 of the present invention has a structure similar to that of the semiconductor laser device 200 according to the aforementioned second embodiment.

Referring to FIG. 2, an oxide film 182 constituting a facet coating film 18 provided on a cavity facet 2a consists of a nitrogen-containing HfAlO film (HfAlON film which is substantially an oxynitride film, refractive index: about 2.05) in the nitride-based semiconductor laser device 700 according to Example 5 of the present invention. A reflectance control film 183 consists of an Al₂O₃ film (refractive index: about 1.65) having a thickness of about 82 nm.

An oxide film 192 constituting a facet coating film 19 provided on a cavity facet 2b consists of a nitrogen-containing HfAlO film (HfAlON film which is substantially an oxynitride film, refractive index: about 2.05) having a thickness of about 100 nm. The structure of a multilayer reflecting film 93 is similar to that of the multilayer reflecting film 93 of the nitride-based semiconductor laser device 300 according to Example 1.

The facet coating films 18 and 19 having the aforementioned structures are so formed that reflectance values on the sides of the cavity facets 2a and 2b with respect to a laser beam having a wavelength of about 405 nm are about 8% and about 98% respectively. In the nitride-based semiconductor laser device 700 according to Example 5, side facets on the sides of the cavity facets 2a and 2b function as a light-emitting surface (front facet) and a light-reflecting surface (rear facet) respectively.

The structure of a semiconductor element layer 2 of the nitride-based semiconductor laser device 700 according to Example 5 is similar to that of the semiconductor element layer 2 of the nitride-based semiconductor laser device 300 according to Example 1. The nitride-based semiconductor laser device 700 having a lasing wavelength λ of about 405 nm is constituted in the aforementioned manner.

In the nitride-based semiconductor laser device 700, as hereinabove described, the facet coating films 18 and 19 provided on the cavity facets 2a and 2b have the oxide films 182 and 192 consisting of the HfAlON films which are substantially oxynitride films. The oxide films 182 and 192 of such a material have a crystallization temperature of at least 1000° C. and are superior in thermal stability as compared with HfO₂, whereby optical characteristics are hard to change even if the facet coating films 18 and 19 remarkably generate heat. Further, the oxide films 182 and 192 contain nitrogen and are formed to be in contact with the cavity facets 2a and 2b respectively, whereby diffusion of oxygen from the external atmosphere into the cavity facets 2a and 2b can be suppressed. Thus, the interfaces between the cavity facets 2a and 2b and the facet coating films 18 and 19 are hard to deteriorate. Consequently, the nitride-based semiconductor laser device 700 can be improved in reliability.

In the nitride-based semiconductor laser device 700, the thicknesses of the oxide films 182 and 192 are preferably in the range of about 20 nm to about 200 nm. According to this structure, separation or the like of the facet coating films 18 and 19 resulting from stress can be suppressed, while diffusion of oxygen from the external atmosphere into the facet coating films 18 and 19 can also be suppressed.

In the nitride-based semiconductor laser device 700, as hereinabove described, the reflectance control film 183 contains Al contained in the oxide film 182, whereby the adhesiveness between the oxide film 182 and the reflectance control film 183 is improved in the facet coating film 18. Thus, separation of the facet coating film 18 can be suppressed. The remaining effects of Example 5 are similar to those of Example 1.

### Third Embodiment

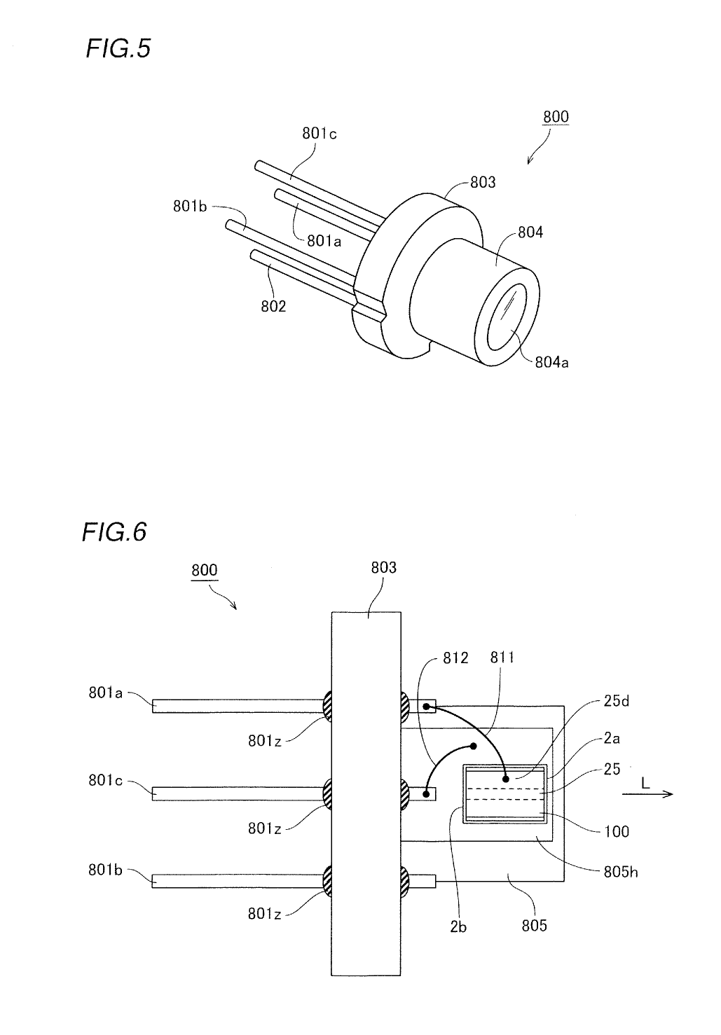

The structure of a laser unit 800 according to a third embodiment of the present invention is now described with reference to FIGS. 5 and 6.

The laser unit 800 according to the third embodiment of the present invention is mounted with the semiconductor laser device 100 according to the aforementioned first embodiment.

The laser unit 800 includes a can package body 803 of a conductive material having a substantially circular shape, power feeding pins 801a, 801b, 801c and 802 and a lid body 804. The semiconductor laser device 100 according to the aforementioned first embodiment is provided on the can package body 803, and sealed with the lid body 804. The lid body 804 is provided with an extraction window 804a of a material transmitting the laser beam. The power feeding pin 802 is mechanically and electrically connected with the can package body 803. The power feeding pin 802 is employed as an earth terminal. Ends of the power feeding pins 801a, 801b, 801c and 802 extending outward from the can package body 803 are connected to a driving circuit (not shown).

A conductive submount 805h is provided on a conductive support member 805 integrated with the can package body 803. The support member 805 and the submount 805h are made of a material excellent in conductivity and thermal conductivity. The semiconductor laser device 100 is so bonded that the laser beam emitting direction L is directed to the outer side of the laser unit 800 (toward the extraction window 804a) and a light-emitting point (the waveguide formed under the ridge portion 2c) of the semiconductor laser device 100 is positioned on the centerline of the laser unit 800.

The power feeding pins 801a, 801b and 801c are electrically insulated from the can package body 803 by respective insulating rings 801z. The power feeding pin 801a is connected to the upper surface of the surface electrode 4 of the semiconductor laser device 100 through a wire 811. The power feeding pin 801c is connected to the upper surface of the submount 805h through a wire 812.

The laser unit 800 according to the third embodiment employs the semiconductor laser device 100 according to the aforementioned first embodiment, whereby the reliability thereof can be improved also when the wavelength of the laser beam is shortened and the output thereof is increased.

### Fourth Embodiment

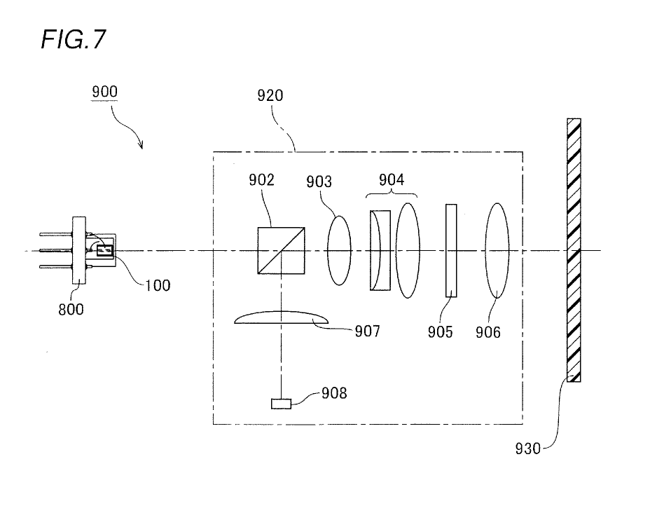

The structure of an optical pickup 900 according to a fourth embodiment of the present invention is now described with reference to FIG. 7. The optical pickup 900 is an example of the “optical apparatus” in the present invention.

The optical pickup 900 according to the fourth embodiment of the present invention stores the laser unit 800 according to the aforementioned third embodiment.

The optical pickup 900 includes the laser unit 800 mounted with the semiconductor laser device 100 according to the aforementioned first embodiment and an optical system 920 having a polarizing beam splitter (hereinafter abbreviated as a polarized BS) 902, a collimator lens 903, a beam expander 904, a λ/4 plate 905, an objective lens 906, a cylindrical lens 907 and a light detection portion 908.

The optical system 920 can adjust the laser beam emitted from the semiconductor laser device 100 as follows: First, the polarizing BS 902 totally transmits the laser beam emitted from the semiconductor laser device 100, and totally reflects a laser beam fed back from an optical disk 930. The collimator lens 903 converts the laser beam emitted from the semiconductor laser device 100 and transmitted through the polarizing BS 902 to a parallel beam. The beam expander 904 is constituted of a concave lens, a convex lens and an actuator (not shown). The actuator varies the distance between the concave lens and the convex lens in response to servo signals from a servo circuit (not shown). Thus, a wavefront state of the laser beam emitted from the semiconductor laser device 100 is corrected.

The λ/4 plate 905 converts the linearly polarized laser beam, substantially converted to the parallel beam by the collimator lens 903, to a circularly polarized beam. Further, the λ/4 plate 905 converts the circularly polarized laser beam fed back from the optical disk 930 to a linearly polarized beam. In this case, the direction of polarization of the linearly polarized beam is orthogonal to the direction of polarization of the linearly polarized laser beam emitted from the semiconductor laser device 100. Thus, the polarized BS 902 substantially totally reflects the laser beam fed back from the optical disk 930. The objective lens 906 converges the laser beam transmitted through the λ/4 plate 905 on the surface (recording layer) of the optical disk 930. The objective lens 906 is movable in a focus direction, a tracking direction and a tilt direction by an objective lens actuator (not shown) in response to the servo signals (a tracking servo signal, a focus servo signal and a tilt servo signal) from the servo circuit.

The cylindrical lens 907 and the light detection portion 908 are arranged to be along the optical axis of the laser beam totally reflected by the polarized BS 902. The cylindrical lens 907 provides the incident laser beam with astigmatic action. The light detection portion 908 outputs a playback signal on the basis of the intensity distribution of the received laser beam. The light detecting portion 908 has a detection region of a prescribed pattern, to obtain a focus error signal, a tracking error signal and a tilt error signal along with the playback signal. The actuator for the beam expander 904 and the objective lens actuator are feedback-controlled by the focus error signal, the tracking error signal and the tilt error signal. The optical pickup 900 according to the fourth embodiment of the present invention is constituted in the aforementioned manner.

The optical pickup 900 according to the fourth embodiment employs the semiconductor laser device 100 according to the aforementioned first embodiment and the laser unit 800 according to the aforementioned third embodiment, whereby the reliability thereof can be improved also when the wavelength of the laser beam is shortened and the output thereof is increased.

Although the present invention has been described and illustrated in detail, it is clearly understood that the same is by way of illustration and example only and is not to be taken by way of limitation, the spirit and scope of the present invention being limited only by the terms of the appended claims.

For example, while the facet coating films 8 and 9 or 18 and 19 formed on the cavity facets 2a and 2b have the multilayer structures of the nitride films and the oxide films of HfSiO or HfAlO or the oxide films of HfSiO or HfAlO containing nitrogen in each of the aforementioned embodiments and Examples, the present invention is not restricted to this, but only one of the facet coating films 8 and 9 or 18 and 19 may have the aforementioned structure. In this case, the more easily altered facet coating film 8 or 18 serving as the light-emitting surface (front facet) preferably has the aforementioned structure.

One of the facet coating films 8 and 9 or 18 and 19 provided on the cavity facets 2a and 2b may have a multilayer structure of a nitride film and an oxide film made of HfSiO or HfAlO and the other one of the facet coating films 8 and 9 or 18 and 19 may have an oxide film made of HfSiO or HfAlO containing nitrogen.

The multilayer reflecting film 93 constituting the facet coating film 9 or 19 may be formed by stacking dielectric films containing another oxide, another nitride or another oxynitride in each of the aforementioned embodiments and Examples. Similarly, the reflectance control film 183 may be formed by a dielectric film containing another oxide, another nitride or another oxynitride in each of the aforementioned second embodiment and Example 5.

In each of the aforementioned embodiments and Examples, still another dielectric film may be formed on the surface side (opposite to the side in contact with the semiconductor element layer 2) of the facet coating film 2a, i.e., on the oxide film 82 or the reflectance control film 183. Similarly, still another dielectric film may be formed on the surface side (opposite to the side in contact with the semiconductor element layer 2) of the facet coating film 2b, i.e., on the multilayer reflecting film 93.

As the nitride films 81 and 91 each consisting of the two-layer film are employed in Example 4, each of the nitride films and the oxide films constituting the facet coating films 8 and 9 or 18 and 19 may be constituted of a multilayer film having at least two layers in each of the remaining embodiments and Examples. In this case, the stacked layers preferably contain a common element.

While the oxide films 82 and 92 or 182 and 192 contain either Si or Al in each of Examples, the present invention is not restricted to this, but the oxide films 82 and 92 or 182 and 192 may contain both of Si and Al.

While the semiconductor element layer 2 is made of the nitride-based semiconductor in each of Examples, the present invention is not restricted to this. According to the present invention, the semiconductor element layer may be made of another semiconductor.

While the aforementioned fourth embodiment describes the optical pickup 900 as an example of the optical apparatus, the present invention is not restricted to this, but is also applicable to a display such as a projector.

What is claimed is:

1. A semiconductor laser device comprising:
a semiconductor element layer having an active layer and a cavity facet; and
a facet coating film arranged on said cavity facet, wherein
said facet coating film includes an oxide film made of hafnium silicate (HfSiO) or hafnium aluminate (HfAlO), and
said facet coating film further has a nitrogen-containing film, in contact with said cavity facet, between said cavity facet and said oxide film.

2. The semiconductor laser device according to claim 1, wherein
said nitrogen-containing film is a nitride film containing an element, i.e., at least either Si or Al, contained in said oxide film.

3. The semiconductor laser device according to claim 1, wherein
said nitrogen-containing film includes a first oxynitride film, in contact with said cavity facet, between said cavity facet and said oxide film.

4. The semiconductor laser device according to claim 3, wherein
said first oxynitride film contains an element, i.e., at least either Si or Al, contained in said oxide film.

5. The semiconductor laser device according to claim 1, wherein
said facet coating film further has a second oxynitride film arranged between said oxide film and said nitrogen-containing film.

6. The semiconductor laser device according to claim 5, wherein
said second oxynitride film contains an element, i.e., at least either Si or Al, contained in said oxide film.

7. The semiconductor laser device according to claim 1, wherein
said cavity facet includes a light-emitting surface and a light-reflecting surface, and
said facet coating film is arranged on said light-emitting surface.

8. The semiconductor laser device according to claim 1, wherein
said cavity facet includes a light-emitting surface and a light-reflecting surface,
said facet coating film is arranged on said light-reflecting surface,
said facet coating film further has a first reflectance control film controlling reflectance of said light-reflecting surface, and
said first reflectance control film is arranged on a surface of said facet coating film opposite to said light-reflecting surface.

9. The semiconductor laser device according to claim 8, wherein
said first reflectance control film includes a film of an oxide in contact with said oxide film.

10. The semiconductor laser device according to claim 9, wherein
said film of said oxide is made of a silicon oxide.

11. The semiconductor laser device according to claim 8, wherein
said first reflectance control film consists of a multilayer film having a high refractive index film and a low refractive index film alternately stacked with each other, and
said high refractive index film is arranged on a surface of said first reflectance control film opposite to said light-reflecting surface.

12. The semiconductor device according to claim 1, having a relation of
t1<λ/(4×n1), t2<λ/(4×n2) and t1<t2, where λ, n1, n2, t1 and t2 represent the wavelength of a laser beam emitted from said active layer, the refractive index of said oxide film, the refractive index of said nitrogen-containing film, the thickness of said oxide film and the thickness of said nitrogen-containing film respectively.

13. The semiconductor laser device according to claim 1, having a relation of
w+x1≦y+z or w+x2≦y+z, where w, x1, x2, y and z (w>0, x1≧0, x2≧0, y>0 and z≧0, at least either x1 or x2 is nonzero) represent the atomic number ratios of Hf, Si, Al, oxygen and nitrogen in said facet coating film respectively.

14. A semiconductor laser device comprising:
a semiconductor element layer having an active layer and a cavity facet; and
a facet coating film arranged on said cavity facet, wherein
said facet coating film includes an oxide film made of hafnium silicate (HfSiO) containing nitrogen or hafnium aluminate (HfAlO) containing nitrogen, and
said oxide film is in contact with said cavity facet.

15. The semiconductor laser device according to claim 14, wherein
said cavity facet includes a light-emitting surface and a light-reflecting surface, and
said facet coating film is arranged on said light-emitting surface.

16. The semiconductor laser device according to claim 14, wherein
said cavity facet includes a light-emitting surface and a light-reflecting surface,
said facet coating film is arranged on said light-reflecting surface,
said facet coating film further has a second reflectance control film controlling reflectance of said light-reflecting surface,
said second reflectance control film is arranged on a surface of said oxide film opposite to said light-reflecting surface, and
said second reflectance control film contains an element, i.e., at least either Si or Al, contained in said oxide film.

17. The semiconductor laser device according to claim 14, wherein
said cavity facet includes a light-emitting surface and a light-reflecting surface,
said facet coating film is arranged on said light-reflecting surface,
said facet coating film further has a third reflectance control film controlling reflectance of said light-reflecting surface,
said third reflectance control film is arranged on a surface of said oxide film opposite to said light-reflecting surface,
said third reflectance control film consists of a multilayer film having a high refractive index film and a low refractive index film alternately stacked with each other, and
said high refractive index film is arranged on a surface of said third reflectance control film opposite to said light-reflecting surface.

18. The semiconductor laser device according to claim 15, having a relation of
w+x1≦y+z or w+x2≦y+z, where w, x1, x2, y and z (w>0, x1≧0, x2≧0, y>0 and z≧0, at least either x1 or x2 is nonzero) represent the atomic number ratios of Hf, Si, Al, oxygen and nitrogen in said oxide film containing nitrogen respectively.

19. The semiconductor laser device according to claim 1, wherein
said semiconductor element layer is made of a nitride-based semiconductor.

20. An optical apparatus comprising:
a semiconductor laser device including a semiconductor element layer provided with an active layer and a cavity facet and a facet coating film arranged on said cavity facet; and
an optical system adjusting a laser beam emitted from said semiconductor laser device, wherein
said facet coating film has an oxide film made of hafnium silicate (HfSiO) or hafnium aluminate (HfAlO),
said facet coating film further has a nitrogen-containing film, in contact with said cavity facet, between said cavity facet and said oxide film, or
said oxide film further contains nitrogen, and is in contact with said cavity facet.
